(19) United States
(12) Patent Application Publication
(10) Pub. No.: US 2025/0273476 A1
(43) Pub. Date: Aug. 28, 2025

(54) METHODS OF FORMING LOW RESISTIVITY FILMS USING Microwave treatment

(71) Applicant: Applied Materials, Inc., Santa Clara, CA (US)

(72) Inventors: Mohammad Mahdi TAVAKOLI, Santa Clara, CA (US); Yoon Ah SHIN, Santa Clara, CA (US); Avgerinos V. GELATOS, Scotts Valley, CA (US); Joung Joo LEE, San Jose, CA (US); Bencherki MEBARKI, Santa Clara, CA (US)

(21) Appl. No.: 18/590,102

(22) Filed: Feb. 28, 2024

(51) Int. Cl. H01L 21/321; H01L 21/67; H01L 21/768

(52) U.S. Cl. CPC H01L 21/321; H01L 21/67017; H01L 21/67115; H01L 21/76883

(57) ABSTRACT

According to one or more embodiments, a method includes exposing a semiconductor device structure to a microwave process to cause impurities within at least one electrical connection formed in at least one feature of the semiconductor device structure to rise to a surface of the at least one electrical connection, and exposing the semiconductor device structure to a reactive gas to remove the impurities from the surface of the at least one electrical connection.

### BACKGROUND

### Field

Embodiments of the present disclosure generally relate to a method and apparatus for forming low resistivity electrical connections.

### Description of the Related Art

Integrated circuits have evolved into complex devices that can include millions of transistors, capacitors, and resistors on a single chip. In the course of integrated circuit evolution, functional density (i.e., the number of interconnected devices per chip area) has generally increased while geometry size (i.e., the smallest component (or line) that can be created using a fabrication process) has decreased.

Microelectronic devices are fabricated on a semiconductor substrate as integrated circuits in which various conductive layers are interconnected with one another to permit electronic signals to propagate within the device. Examples of such devices include memory (e.g., dynamic random access memory (DRAM)) and logic devices, including both planar and three-dimensional structures. Three-dimensional structures include fin field-effect transistor (finFET) or metal-oxide-semiconductor field-effect transistor (MOSFET) devices.

Traditional middle-end-of-the-line (MEOL) electrical connections are formed in a feature, also referred to as a via, a trench, or the like, in the semiconductor substrate. MEOL electrical connections allow connections between front-end-of-the-line (FEOL) semiconductor structures and back-end-of-the-line (BEOL) interconnects. Electrical connections with a low resistivity are desirable in semiconductor devices. However, when MEOL electrical connections have high resistance, the electrical connections produce poor connections between the FEOL structures and the BEOL interconnects, reducing the performance of the packaged semiconductor structures. For example, MEOL electrical connections may have a resistivity due to a high level of impurities present in the electrical connection (i.e., the conductive material deposited in the feature to form the electrical connection).

Typically to reduce the level of impurities in the electrical connection, the electrical connections are treated using a plasma process. However, the plasma process is a surface based method and is not able to penetrate (treat) the bulk of the conductive material. Thus, there is a need for improved methods to reduce electrical connections and simplified processes of contact formation.

### SUMMARY

According to one or more embodiments a method includes exposing a semiconductor device structure to a microwave process to cause impurities within at least one electrical connection formed in at least one feature of the semiconductor device structure to rise to a surface of the at least one electrical connection, and exposing the semiconductor device structure to a reactive gas to remove the impurities from the surface of the at least one electrical connection.

According to one or more embodiments, a processing tool includes a controller, and a memory for storing instructions, which, when executed by the controller, causes the controller to perform a method for treating an electrical connection formed in a feature of a semiconductor structure, the method comprising exposing a semiconductor device structure to a microwave process to cause impurities within at least one electrical connection formed in at least one feature of the semiconductor device structure to rise to a surface of the at least one electrical connection, and exposing the semiconductor device structure to a reactive gas to remove the impurities from the surface of the at least one electrical connection.

According to one or more embodiments, a method includes exposing a semiconductor device structure to a microwave process to cause impurities in an electrical connection comprising ruthenium (Ru) that is formed in a feature of the semiconductor device structure to rise to a surface of electrical connection, and exposing the semiconductor device structure to hydrogen to remove the impurities from the surface of the electrical connection.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, as the disclosure may admit to other equally effective embodiments.

FIG. 1 illustrates a schematic top view of a multi-chamber processing system, according to embodiments described herein.

FIG. 2 is a flow diagram depicting a method of treating an electrical connection of a semiconductor structure, according to one or more of the embodiments described herein.

FIGS. 3A-3C illustrate views of various stages of treating an electrical connection of a semiconductor structure in accordance with one or more embodiments described herein.

FIGS. 4A-4D, illustrate views of a microwave processing tool is shown, according to embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Middle-end-of-the-line (MEOL) and back-end-of-the-line (BEOL) electrical connections, such as contacts, interconnects, and the like are formed by filling a feature such as a cavity, trench, or via with a conductive material. However, due to impurities within the conductive material, MEOL and BEOL electrical connections have a high resistivity hindering the performance of packaged semiconductor structures. Typically to reduce the amount of impurities in the electrical connection (conductive material), the electrical connections are treated using a plasma process. However, the plasma process is a surface based method and is not able to penetrate (treat) the bulk of the conductive material. Embodiments herein relate to treating the electrical connections with a microwave process that causes the impurities to rise to the surface of the electrical connection and then removing the impurities by exposing the semiconductor structures to a reactive gas.

### Processing System Example

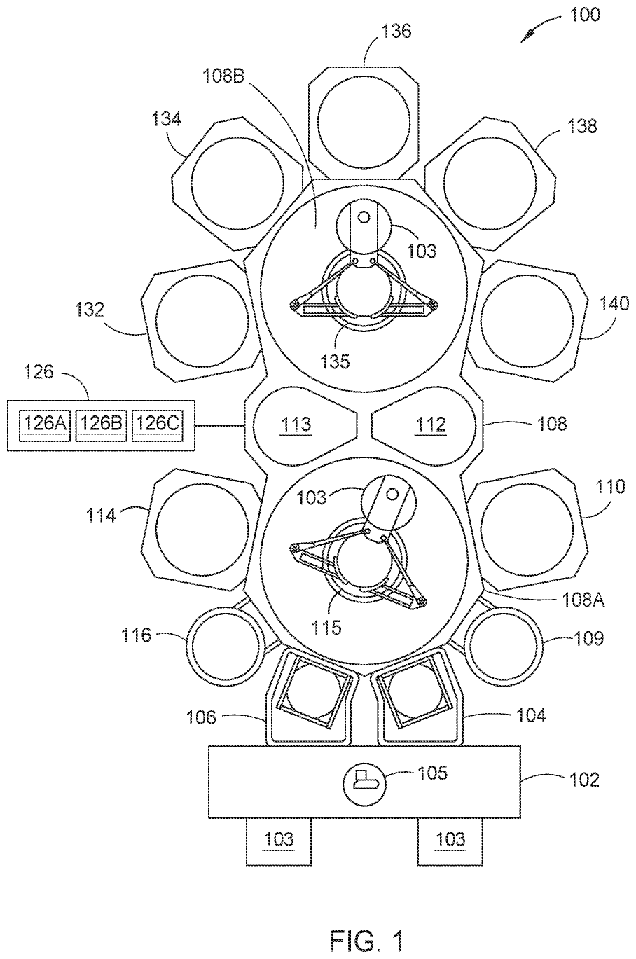

FIG. 1 illustrates a schematic representation of a processing system 100 for use with one or more embodiments of the disclosure. As detailed below, substrates in the processing system 100 may be processed in and transferred between the various chambers without exposing the substrates to an ambient environment exterior to the processing system 100 (for example, an atmospheric ambient environment such as may be present in a fab). For example, the substrates may be processed in and transferred between the various chambers maintained at a pressure (for example, less than or equal to about 500 Torr) or sub-atmospheric pressure, such as a vacuum environment, without breaking the reduced relative pressure or vacuum environment among various processes performed on the substrates in the processing system 100. Accordingly, the processing system 100 may provide for an integrated solution for some processing of substrates.

Examples of a processing system that may be suitably modified in accordance with the teachings provided include the Endura®, Producer® or Centura® integrated processing systems or other suitable processing systems commercially available from Applied Materials, Inc., located in Santa Clara, California (CA), United States of America. One may envision that other processing systems, including those from other manufacturers, may be adapted to benefit from aspects described.

FIG. 1 is a schematic top view of the substrate processing system 100 (also referred to as a “processing platform”), according to embodiments described herein. The processing system can be used for a microwave treatment of a surface of an electrical connection, such as a contact structure, an interconnect, or the like, to remove contaminants and impurities from the surface of the electrical connection. The substrate processing system 100 generally includes an equipment front-end module (EFEM) 102 for loading substrates into the processing system 100, a first load lock chamber 104 and a second load lock chamber 106 coupled to the EFEM 102, a transfer chamber 108 coupled to the first load lock chamber 104 and the second load lock chamber 106, and a plurality of other chambers coupled to the transfer chamber 108 as described in detail below. The EFEM 102 generally includes one or more robots 105 that are configured to transfer substrates from front opening unified pods (FOUPs) 103 to at least one of the first load lock chamber 104 or the second load lock chamber 106. Proceeding counterclockwise around the transfer chamber 108 from the buffer portion 108A of the first load lock chamber 104, the processing system 100 includes a first dedicated degas chamber 109, a first pre-clean chamber 110, a first pass-through chamber 112, a second pass-through chamber 113, a second pre-clean chamber 114, a second degas chamber 116 and the second load lock chamber 106. The buffer portion 108A of the transfer chamber 108 includes a first robot 115 that is configured to transfer substrates to each of the load lock chambers 104, 106, the degas chambers 109, 116, the pre-clean chambers 110, 114 and the pass-through chambers 112, 113.

The back-end portion 108B of the transfer chamber 108 includes a second robot 135 that is configured to transfer substrates to each of the pass-through chambers 112, 113 and the processing chambers coupled to the back-end portion 108B of the processing system 100. The processing chambers can include a first processing chamber 132, a second processing chamber 134, a third processing chamber 136, a fourth processing chamber 138 and a fifth process chamber 140. In general, the processing chambers 132, 134, 136, 138, 140 can include an atomic layer deposition (ALD) chamber, microwave chamber, chemical vapor deposition (CVD) chamber, physical vapor deposition (PVD) chamber, etch chamber, degas chamber, an anneal chamber, or other type of semiconductor substrate processing chamber. In some embodiments, one or more of the processing chambers 132, 134, 136, 138, 140 are a microwave chamber. In some examples, the processing chamber 110 may be capable of performing an etch process, the processing chamber 114 may be capable of performing a cleaning process or an annealing process, and the processing chambers 132, 134, 136, 138, 140 may be capable of performing respective microwave, CVD or ALD deposition processes. In one example, the processing chambers 132, 134, 136, 138, or 140 may be a Volta™ CVD/ALD chamber, or Encore™ PVD chambers available from Applied Materials of Santa Clara, Calif.

A system controller 126, such as a programmable computer, is coupled to the processing system 100 for controlling one or more of the components therein. For example, the system controller 126 may control the operation of one or more of the processing chambers, such as processing chambers 132, 134, 136, 138, 140. In operation, the system controller 126 enables data acquisition and feedback from the respective components to coordinate processing in the processing system 100.

The system controller 126 includes a programmable central processing unit (CPU) 126A, which is operable with a memory 126B (for example, non-volatile memory) and support circuits 126C. The support circuits 126C (for example, cache, clock circuits, input/output subsystems, power supplies, etc., and combinations thereof) are conventionally coupled to the CPU 126A and coupled to the various components within the processing system 100.

In some embodiments, the CPU 126A is one of any form of general purpose computer processor used in an industrial setting, such as a programmable logic controller (PLC), for controlling various monitoring system component and sub-processors. The memory 126B, coupled to the CPU 126A, is non-transitory and is typically one or more of readily available memory such as random access memory (RAM), read only memory (ROM), floppy disk drive, hard disk, or any other form of digital storage, local or remote.

Herein, the memory 126B is in the form of a computer-readable storage media containing instructions (for example, non-volatile memory), that when executed by the CPU 126A, facilitates the operation of the processing system 100. The instructions in the memory 126B are in the form of a program product such as a program that implements the methods of the present disclosure (for example, middleware application, equipment software application, etc.). The program code may conform to any one of a number of different programming languages. In one example, the disclosure may be implemented as a program product stored on computer-readable storage media for use with a computer system. The program(s) of the program product define functions of the embodiments (including the methods described herein). Illustrative computer-readable storage media include, but are not limited to: (i) non-writable storage media (for example, read-only memory devices within a computer such as CD-ROM disks readable by a CD-ROM drive, flash memory, ROM chips or any type of solid-state non-volatile semiconductor memory) on which information is permanently stored; and (ii) writable storage media (for example, floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure. The various methods disclosed herein may generally be implemented under the control of the CPU 126A by the CPU 126A executing computer instruction code stored in the memory 126B (or in memory of a particular processing chamber) as, for example, a software routine. When the computer instruction code is executed by the CPU 126A, the CPU 126A controls the chambers to perform processes in accordance with the various methods.

As will be described in more detail below, in one example of the processing system 100, a semiconductor device structure undergoes a microwave process and an exposure to a reactive gas. In some embodiments, the microwave process and the exposure to the reactive gas are performed in different processing chambers. For example, the microwave process may be performed in the first processing chamber 132 and the exposure to the reactive gas may be performed in the second processing chamber 134. In another example, the microwave process and the exposure to the reactive gas may be performed in a same processing chamber, such as the first processing chamber 132.

### Processing Sequence Example

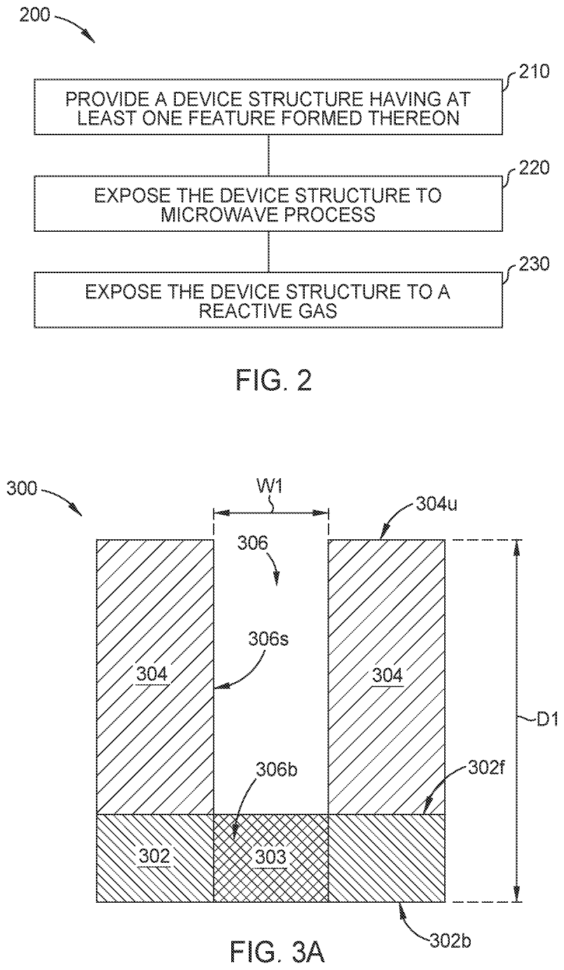

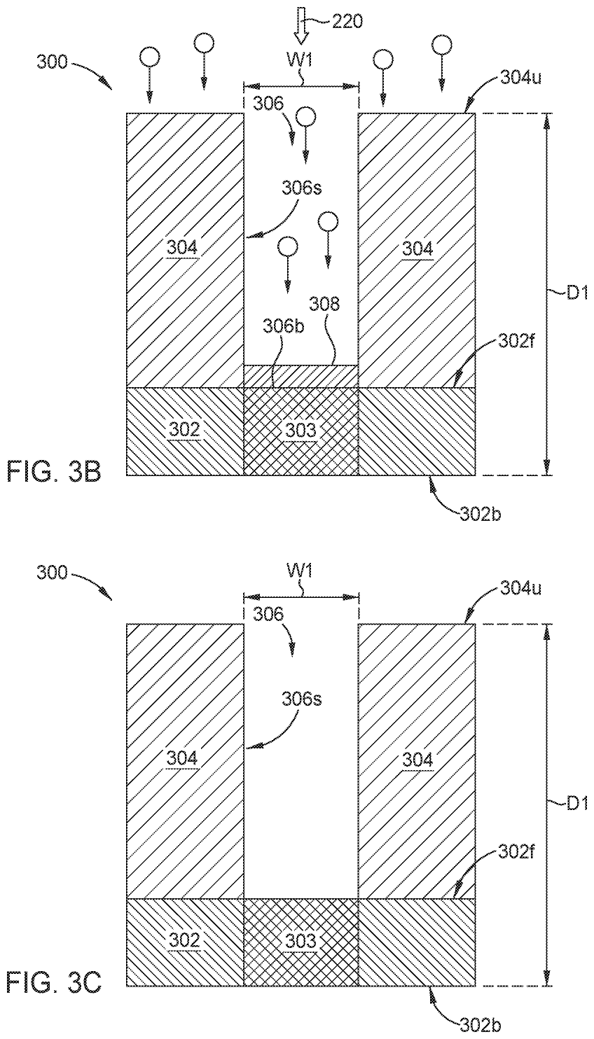

FIG. 2 is a flow diagram depicting a method of treating an electrical connection of a semiconductor structure, according to one or more of the embodiments described herein. FIGS. 3A-3C illustrate views of various stages of treating an electrical connection of a semiconductor structure in accordance with one or more embodiments described herein. Although FIGS. 3A-3C are described in relation to the method 200, the structures disclosed in FIGS. 3A-3C are not limited to the method 200, but instead may stand alone as structures independent of the method 200. Similarly, although the method 200 is described in relation to FIGS. 3A-3C, the method 200 is not limited to the structures disclosed in FIGS. 3A-3C but instead may stand alone independent of the structures disclosed in FIGS. 3A-3C. It should be understood that FIGS. 3A-3C illustrate only partial schematic views of the semiconductor device structure 300, and the semiconductor device structure 300 may contain any number of transistor sections and additional materials having aspects as illustrated in the figures. It should also be noted that although the method 200 illustrated in FIG. 2 is described sequentially, other process sequences that include one or more operations that have been omitted and/or added, and/or has been rearranged in another desirable order, fall within the scope of the embodiments of the disclosure provided herein.

The term “substrate” as used herein refers to a layer of material that serves as a basis for subsequent processing operations. The substrate may be a silicon based material or any suitable insulating materials or conductive materials as needed. The substrate may include a material such as crystalline silicon (e.g., Si<100> or Si<111>), silicon oxide, strained silicon, silicon germanium, doped or undoped polysilicon, doped or undoped silicon wafers and patterned or non-patterned wafers, silicon on insulator (SOI), carbon doped silicon oxides, silicon nitride, doped silicon, germanium, gallium arsenide, glass, or sapphire.

Referring to FIG. 2, at operation 210, a semiconductor device structure 300 having a feature formed therein is provided. FIG. 3A illustrates a cross-sectional view of the semiconductor device structure 300 during intermediate stages of manufacturing corresponding to the operation 210. The semiconductor device structure 300 includes a device substrate 302 having one or more layers formed thereon, for example, a dielectric layer 304 as is shown in FIG. 3A. The device substrate 302 may be or include a bulk semiconductor substrate, a semiconductor-on-insulator (SOI) substrate, or the like, which may be doped (e.g., with a p-type dopant or an n-type dopant) or undoped. In some embodiments, the semiconductor material of the device substrate 302 may include an elemental semiconductor, for example, such as silicon (Si) or germanium (Ge); a compound semiconductor including, for example, silicon carbide, gallium arsenide, gallium phosphide, indium phosphide, indium arsenide, and/or indium antimonide; an alloy semiconductor including, for example, SiGe, GaAsP, AlInAs, GaInAs, GaInP, and/or GaInAsP; a combination thereof, or the like. The device substrate 302 may include additional materials, for example, silicide layers, metal silicide layers, metal layers, dielectric layers, etch stop layers, interlayer dielectrics, or a combination thereof.

The device substrate 302 may further include integrated circuit devices (not shown). As one of ordinary skill in the art will recognize, a wide variety of integrated circuit devices such as transistors, diodes, capacitors, resistors, the like, or combinations thereof may be formed in and/or on the device substrate 302 to generate the structural and functional requirements of the design for the resulting semiconductor device structure 300.

The device substrate 302 has a frontside 302f (also referred to as a front surface) and a backside 302b (also referred to as a back surface) opposite the frontside 302f. The dielectric layer 304 is formed over the frontside 302f of the device substrate 302. The dielectric layer 304 may include multiple layers. The dielectric layer 304 includes an upper surface 304u or field region. In some embodiments, the dielectric layer 304 includes a dielectric material, such as a low k dielectric (SiCOH), silicon oxide, silicon dioxide (SiO₂), silicon nitride (Si₃N₄), silicon carbide (SiC), silicon oxynitride (SiON), aluminum oxide (Al₂O₃), aluminum nitride (AlN), a combination thereof, or multi-layers thereof. In some embodiments, the dielectric layer 304 consists essentially of silicon oxide. It is noted that the foregoing descriptors for example, silicon oxide, should not be interpreted to disclose any particular stoichiometric ratio. Accordingly, “silicon oxide” and the like will be understood by one skilled in the art as a material consisting essentially of silicon and oxygen without disclosing any specific stoichiometric ratio.

The semiconductor device structure 300 is patterned to form one or more feature(s) 306. The feature 306 may be a high aspect ratio (HAR) feature. In some embodiments, the feature 306 can be selected from, but not limited to, a trench, a via, a hole, a cavity, or a combination thereof. In particular embodiments, the feature is a trench. In other particular embodiments, the feature 306 is a via. In some embodiments, the feature 306 extends from the upper surface 304u of the dielectric layer 304 towards the backside 302b of the device substrate 302. The feature 306 includes sidewall surface(s) 306s that extend from the field region 304u to the backside 302b.

In some embodiments, an electrical connection, such as electrical connection 303 is formed within the feature 306. The electrical connection 303 may be an interconnect, a contact structure, or the like. The electrical connection 303 may be formed by depositing a conductive material into the feature 306. The conductive material may be deposited such that the conductive material fills the entire or at least a portion of the feature 306. For example, as shown in FIG. 3A, the electrical connection 303 may be a contact structure formed by filling a bottom portion 306b of the feature 306 with a conductive material. In some embodiments, the bottom portion 306b is defined by (extends between) the frontside 302f and the backside 302b of the device substrate 302. Therefore, the electrical connection 303 may extend between the frontside 302f and the backside 302b of the device substrate 302 (or any other portion of the feature 306, including the entire feature 306). The conductive material may be formed of copper (Cu), cobalt (Co), molybdenum (Mo), tungsten (W), or ruthenium (Ru). The feature 306 has a first depth “D1” from the upper surface 304u to the backside 302b and a width “W1” between the two sidewall surface(s) 306s. In some embodiments, the depth D1 is in a range of 2 nm to 200 nm. In some embodiments, the width W1 is in a range of 10 nm to 100 nm. In some embodiments, the feature 306 has an aspect ratio (D/W) in a range of 1 to 20.

In some embodiments, the electrical connection 303 has a high resistivity due to a high amount of contaminants (impurities) that reside in the conductive material. Embodiments herein relate to heating the semiconductor device structure 300 using a microwave process, causing the impurities to rise to the surface of the electrical connection 303, and then exposing the semiconductor device structure 300 (i.e., the conductive material) to reactive gas to remove the impurities and reduce the resistivity of the electrical connection 303.

Referring to FIG. 2, at operation 220, the semiconductor device structure 300 is exposed to (i.e., undergoes) a microwave process. FIG. 3B illustrates a cross-sectional view of a semiconductor device structure 300 during the microwave process corresponding to the operation 220. The microwave process of operation 220 can include exposing the semiconductor device structure 300 to microwaves in a processing chamber such as the first processing chamber 132 (FIG. 1). The microwave process of operation 220 can include one or more exposures to microwaves. In one or more examples, the semiconductor device may be exposed to microwaves having a frequency between 300 MHz and 1000 GHz at a power between 100-500 W for a time period between 5-30 min in a processing chamber maintained at a temperature between 300-450° C. and at a pressure between 50-500 mTorr. As shown in FIG. 3B, during the microwave process, microwaves contact the dielectric layer 304 and the electrical connection 303 and heats the electrical connection 303 more than the dielectric layer 304 because the electrical connection is made from a conductive material. Advantageously the microwaves react with the conductive material and cause a layer of impurities 308 to form on the surface of the electrical connection 303. Stated differently, the microwaves react with the conductive material and force all the impurities to the surface of the electrical connection 303. For example, the microwaves penetrate the bulk of the electrical connection 303 and expose a layer of impurities on the surface of the electrical connection 303. For example, if the conductive material is Ru, the layer of impurities 308 may include, but are not limited to, carbon, iodine or the like. In another example the layer of impurities 308 may include an oxide layer formed on the surface of the electrical connection 303.

At operation 230, as shown in FIG. 3C, the semiconductor device structure 300 is exposed to a reactive gas in a processing chamber. The exposure to the reactive gas may be performed in a same or different processing chamber than the microwave process. In one or more examples, the reactive gas includes, but is not limited to hydrogen. In one example, the exposure to the reactive gas removes the layer of impurities 308. Advantageously, the microwave process causes the impurities to rise to the surface of the contact structure without the use of plasma. This reduces damage to the dielectric layer 304, improves the quality of the conductive material (removes the impurities), exposes the impurities (i.e., layer of impurities 308) so the impurities are easily removed, removes an oxide layer formed on the surface of the electrical connection 303, and reduces the resistivity of the electrical connection 303.

### Processing Chamber Example

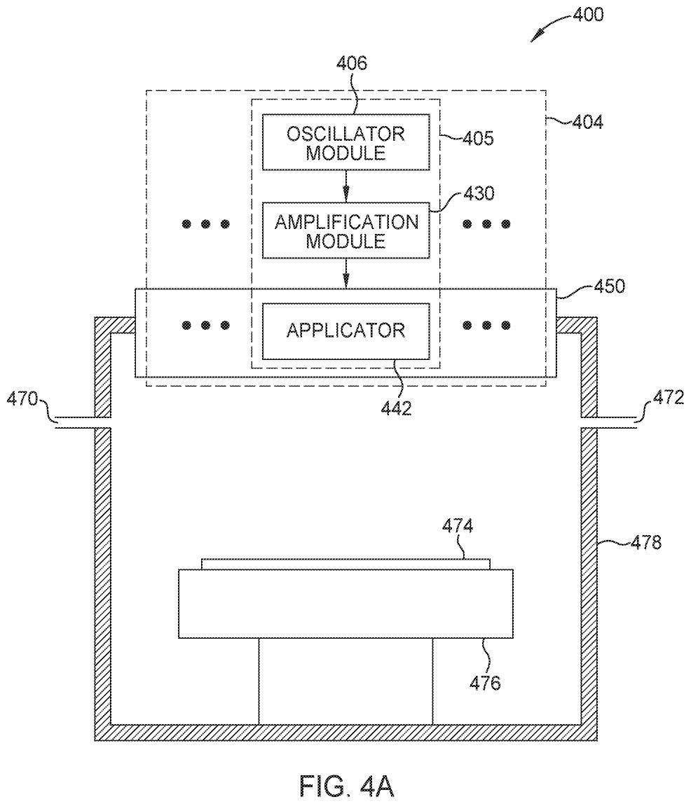

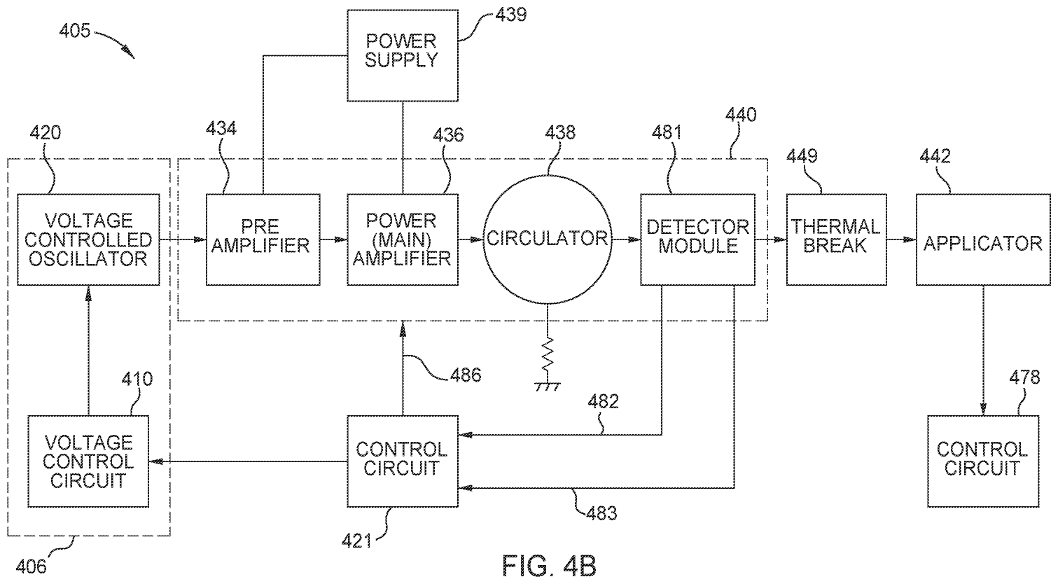

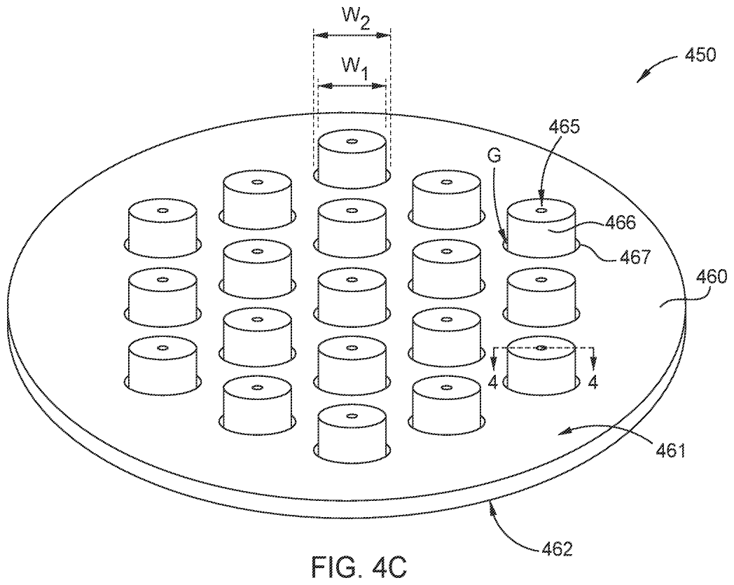

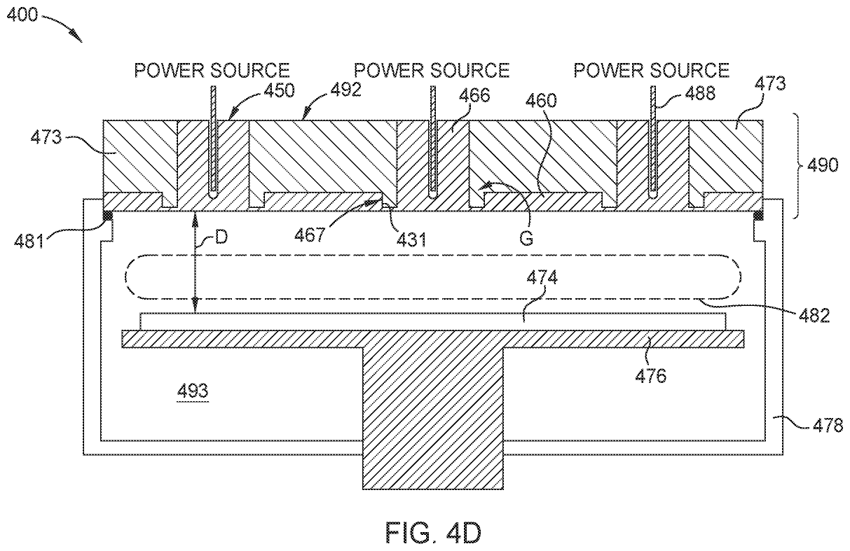

Referring now to FIGS. 4A-4D, a series of illustrations depicting an example of a microwave processing tool 400 is shown, in accordance with an embodiment. The microwave processing tool 400 is configured to deliver microwave energy to a processing region of the process chamber to remove impurities from the electrical connection 303 (FIGS. 3A-3C).

Referring now to FIG. 4A, a cross-sectional illustration of a microwave processing tool 400 (referred to as processing tool 400 for short) is shown, according to an embodiment. In some embodiments, the processing tool 400 may be a processing tool suitable for any type of processing operation that requires the delivery of microwave energy. In some embodiments, one or more of the chambers 110 and 114, or even chambers 132-140, may include the processing tool 400. The processing tool may emit high-frequency electromagnetic radiation in the form of microwave energy. In some embodiments, “High-frequency” may refer to frequencies between 300 MHz and 1000 GHz.

Generally, embodiments include a processing tool 400 that includes a chamber 478. In the processing tool 400, the chamber 478 may be a vacuum chamber. A vacuum chamber may include a pump (not shown) for removing gases from the chamber to provide the desired vacuum. Additional embodiments may include a chamber 478 that includes one or more gas lines 470 for providing processing gases into the chamber 478 and exhaust lines 472 for removing byproducts from the chamber 478. While not shown, it is to be appreciated that gas may also be injected into the chamber 478 through a source array 450 (e.g., as a showerhead) for evenly distributing the processing gases over a workpiece 474 (e.g., wafer, substrate, etc.).

In an embodiment, the workpiece 474 may be supported on a chuck 476. For example, the chuck 476 may be any suitable chuck, such as an electrostatic chuck. The chuck 476 may also include cooling lines and/or a heater to provide temperature control to the workpiece 474 during processing. Due to the modular configuration of the high-frequency emission modules described herein, embodiments allow for the processing tool 400 to accommodate any sized workpiece 474. For example, the workpiece 474 may be a semiconductor wafer (e.g., 200 mm, 300 mm, 450 mm, or larger). Alternative embodiments also include workpieces 474 other than semiconductor wafers. For example, embodiments may include a processing tool 400 configured for processing glass substrates, (e.g., for display technologies).

According to an embodiment, the processing tool 400 includes a modular high-frequency emission source 404. The modular high-frequency emission source 404 may comprise an array of high-frequency emission modules 405. In an embodiment, each high-frequency emission module 405 may include an oscillator module 406, an amplification module 430, and an applicator 442. As shown, the applicators 442 are schematically shown as being integrated into the source array 450

In an embodiment, the oscillator module 406 and the amplification module 430 may comprise electrical components that are solid state electrical components. In an embodiment, each of the plurality of oscillator modules 406 may be communicatively coupled to different amplification modules 430. For example, each oscillator module 406 may be electrically coupled to a single amplification module 430. In an embodiment, the plurality of oscillator modules 406 may generate incoherent electromagnetic radiation. Accordingly, the electromagnetic radiation induced in the chamber 478 will not interact in a manner that results in an undesirable interference pattern.

In an embodiment, each oscillator module 406 generates high frequency electromagnetic radiation that is transmitted to the amplification module 430. After processing by the amplification module 430, the electromagnetic radiation is transmitted to the applicator 442. In an embodiment, the applicators 442 each emit electromagnetic radiation into the chamber 478. In some embodiments, the applicators 442 couple the electromagnetic radiation to the processing gases in the chamber 478 to provide energy thereto, without forming a plasma.

Referring now to FIG. 4B, a schematic of a solid state high-frequency emission module 405 is shown, in accordance with an embodiment. In an embodiment, the high-frequency emission module 405 comprises an oscillator module 406. The oscillator module 406 may include a voltage control circuit 410 for providing an input voltage to a voltage controlled oscillator 420 in order to produce high-frequency electromagnetic radiation at a desired frequency. The voltage controlled oscillator 420 is an electronic oscillator whose oscillation frequency is controlled by the input voltage. According to an embodiment, the input voltage from the voltage control circuit 410 results in the voltage controlled oscillator 420 oscillating at a desired frequency.

According to an embodiment, the electromagnetic radiation is transmitted from the voltage controlled oscillator 420 to an amplification module 430. The amplification module 430 may include a driver/pre-amplifier 434, and a main power amplifier 436 that are each coupled to a power supply 439. According to an embodiment, the amplification module 430 may operate in a pulse mode. For example, the amplification module 430 may have a duty cycle between 1% and 99%. In a more particular embodiment, the amplification module 430 may have a duty cycle between approximately 15% and 50%.

In an embodiment, the electromagnetic radiation may be transmitted to the thermal break 449 and the applicator 442 after being processed by the amplification module 430. However, part of the power transmitted to the thermal break 449 may be reflected back due to the mismatch in the output impedance. Accordingly, some embodiments include a detector module 481 that allows for the level of forward power 483 and reflected power 482 to be sensed and fed back to the control circuit module 421. It is to be appreciated that the detector module 481 may be located at one or more different locations in the system (e.g., between the circulator 438 and the thermal break 449). In an embodiment, the control circuit module 421 interprets the forward power 483 and the reflected power 482, and determines the level for the control signal 485 that is communicatively coupled to the oscillator module 406 and the level for the control signal 386 that is communicatively coupled to the amplification module 430. In an embodiment, control signal 485 adjusts the oscillator module 406 to optimize the high-frequency radiation coupled to the amplification module 430. In an embodiment, control signal 486 adjusts the amplification module 430 to optimize the output power coupled to the applicator 442 through the thermal break 449. In an embodiment, the feedback control of the oscillator module 406 and the amplification module 430, in addition to the tailoring of the impedance matching in the thermal break 449, may allow for the level of the reflected power to be less than approximately 5% of the forward power. In some embodiments, the feedback control of the oscillator module 406 and the amplification module 430 may allow for the level of the reflected power to be less than approximately 2% of the forward power.

Referring now to FIG. 4C, a perspective view illustration of a source array 450 is shown, in accordance with an embodiment. In an embodiment, the source array 450 comprises a dielectric plate 460. A plurality of cavities 467 are disposed into a first surface 461 of the dielectric plate 460. The cavities 467 do not pass through to a second surface 462 of the dielectric plate 460. The source array 450 may further include a plurality of dielectric resonators 466. Each of the dielectric resonators 466 may be in a different one of the cavities 467. Each of the dielectric resonators 466 may comprise a hole 465 in the axial center of the dielectric resonator 466.

In an embodiment, the dielectric resonators 466 may have a first width W1, and the cavities 467 may have a second width W2. The first width W1 of the dielectric resonator 466 is smaller than the second width W2 of the cavities 467. The difference in the widths provides a gap G between a sidewall of the dielectric resonators 466 and a sidewall of the cavity 467. In the illustrated embodiment, each of the dielectric resonators 466 are shown as having a uniform width W1. However, it is to be appreciated that not all dielectric resonators 466 of a source array 450 need to have the same dimensions.

Referring now to FIG. 4D, a cross-sectional illustration of a processing tool 400 that includes an assembly 490 is shown, in accordance with an embodiment. In an embodiment, the processing tool comprises a chamber 478 that is sealed by an assembly 490. For example, the assembly 490 may rest against one or more O-rings 495 to provide a vacuum seal to a chamber volume 493 of the chamber 478. In other embodiments, the assembly 490 may interface with the chamber 478. That is, the assembly 490 may be part of a lid that seals the chamber 478. In an embodiment, the processing tool 400 may comprise a plurality of processing volumes (which may be fluidically coupled together), with each processing volume having a different assembly 490. In an embodiment, a chuck 476 or the like may support a workpiece 474. The workpiece 474 may be a distance D from the assembly 490. In an embodiment, the chamber volume 493 may be suitable for delivering microwave energy to a process gas disposed within the chamber 478. That is, the chamber 478 may be a vacuum chamber.

In an embodiment, the assembly 490 comprises a source array 450 and a housing 492. The source array 450 may comprise a dielectric plate 460 and a plurality of dielectric resonators 466 extending up from the dielectric plate 460. Cavities 467 into the dielectric plate 460 may surround each of the dielectric resonators 466. Sidewalls of the cavity 467 are separated from the sidewall of the dielectric resonator 466 by a gap G. The dielectric plate 460 and the dielectric resonators 466 of the source array 450 may be a monolithic structure (as shown in FIG. 4D), or the dielectric plate 460 and the dielectric resonators 466 may be discrete components.

The housing 492 include rings 431 that fit into the gaps G. In an embodiment, the rings 431 and the conductive body 473 of the housing 492 are a monolithic structure (as shown in FIG. 4D), or the conductive body 473 and the rings 431 may be discrete components. The housing 492 may having openings sized to receive the dielectric resonators 466. In an embodiment, monopole antennas 488 may extend into holes in the dielectric resonators 466. The monopole antennas 488 are each electrically coupled to power sources (e.g., high-frequency emission modules 405).

While the foregoing is directed to embodiments of the present disclosure, other and further embodiments of the disclosure may be devised without departing from the basic scope thereof, and the scope thereof is determined by the claims that follow.

What is claimed is:

1. A method comprising:
exposing a semiconductor device structure to a microwave process to cause impurities within at least one electrical connection formed in at least one feature of the semiconductor device structure to rise to a surface of the at least one electrical connection; and
exposing the semiconductor device structure to a reactive gas to remove the impurities from the surface of the at least one electrical connection.

2. The method of claim 1, wherein the at least one electrical connection comprises a conductive material deposited within the at least one feature.

3. The method of claim 2, wherein the conductive material comprises ruthenium (Ru).

4. The method of claim 3, wherein the impurities comprise carbon (C), iodine (I), and combinations thereof.

5. The method of claim 1, wherein the reactive gas comprises hydrogen.

6. The method of claim 1, wherein the impurities further comprise an oxide layer formed on the surface of the electrical connection.

7. The method of claim 1, wherein the semiconductor device structure comprises a dielectric layer formed on a frontside of a device substrate and the semiconductor device structure is patterned to form the at least one feature, wherein the at least one feature extends between a field region of the dielectric layer to a backside of the device substrate.

8. The method of claim 7, wherein the at least one electrical connection is formed within the at least one feature and extends between the frontside of the device substrate and the backside of the device substrate.

9. The method of claim 1, wherein the exposing a semiconductor device structure to a microwave process and the exposing the semiconductor device structure to a reactive gas are performed in a same processing chamber.

10. The method of claim 1, wherein the exposing a semiconductor device structure to a microwave process and the exposing the semiconductor device structure to a reactive gas are performed in different processing chambers.

11. A processing tool comprising:
a controller; and
a memory for storing instructions, which, when executed by the controller, causes the controller to perform a method for treating an electrical connection formed in a feature of a semiconductor structure, the method comprising:
exposing a semiconductor device structure to a microwave process to cause impurities within at least one electrical connection formed in at least one feature of the semiconductor device structure to rise to a surface of the at least one electrical connection; and
exposing the semiconductor device structure to a reactive gas to remove the impurities from the surface of the at least one electrical connection.

12. The processing tool of claim 11, wherein the processing tool further comprises a first processing chamber configured to perform the exposing a semiconductor device structure to a microwave process and a second processing chamber configured to perform the exposing the semiconductor device structure to a reactive gas to remove the impurities from the surface of the at least one electrical connection.

13. The processing tool of claim 11, wherein the at least one electrical connection comprises a conductive material deposited within the at least one feature.

14. The processing tool of claim 13, wherein the conductive material comprises ruthenium (Ru).

15. The processing tool of claim 14, wherein the impurities comprise carbon (C), iodine (I), and combinations thereof.

16. The processing tool of claim 11, wherein the reactive gas comprises hydrogen.

17. The processing tool of claim 11, wherein the impurities further comprise an oxide layer formed on the surface of the electrical connection.

18. The processing tool of claim 11, wherein the semiconductor device structure comprises a dielectric layer formed on a frontside of a device substrate and the semiconductor device structure is patterned to form the at least one feature, wherein the at least one feature extends between a field region of the dielectric layer to a backside of the device substrate.

19. The processing tool of claim 18, wherein the at least one electrical connection is formed within the at least one feature and extends between the frontside of the device substrate and the backside of the device substrate.

20. A method comprising:
exposing a semiconductor device structure to a microwave process to cause impurities in an electrical connection comprising ruthenium (Ru) that is formed in a feature of the semiconductor device structure to rise to a surface of electrical connection; and
exposing the semiconductor device structure to hydrogen to remove the impurities from the surface of the electrical connection.
